(19) United States
(12) Patent Application Publication
(10) Pub. No.: US 2025/0027201 A1
(43) Pub. Date: Jan. 23, 2025

(54) SUBSTRATE SUPPORTING DEVICE AND SUBSTRATE PROCESSING APPARATUS

(71) Applicant: ADVANCED MICRO-FABRICATION EQUIPMENT INC. CHINA, Shanghai (CN)

(72) Inventors: Yong JIANG, Shanghai (CN); Wei DING, Shanghai (CN)

(21) Appl. No.: 18/714,071

(22) PCT Filed: Sep. 19, 2022
(86) PCT No.: PCT/CN2022/119610

§ 371 Date: May 28, 2024

(30) Foreign Application Priority Data
Dec. 2, 2021 (CN) 202111459188.2

(51) Int. Cl. C23C 16/458

(52) U.S. Cl. CPC C23C 16/4584

(57) ABSTRACT

Provided is a substrate supporting device, including a susceptor and a rotating tube. The susceptor is arranged in the process chamber of a substrate processing apparatus for supporting the substrate; the bottom surface of the susceptor is provided with a first limiting portion; the rotating tube, having a cylindrical structure, is arranged below the susceptor and supports the susceptor, the side wall of the rotating tube is provided with a second limiting portion corresponding to the first limiting portion in position, and relative movement between the rotating tube and the susceptor in the horizontal direction is limited when the two rotate through cooperation of the first limiting portion and the corresponding second limiting portion. The present invention also provides a substrate processing apparatus. According to the present invention, synchronous rotation of the susceptor and the rotating tube can be ensured, thereby enabling the susceptor to be uniformly heated, and ensuring uniformity of substrate surface temperature.

### TECHNICAL FIELD

The present invention relates to the field of chemical vapor deposition, in particular to a substrate supporting device and a substrate processing apparatus.

### BACKGROUND

CVD (Chemical Vapor Deposition) refers to a process in which reactants react on a surface of a substrate to form a thin film under gaseous conditions. CVD apparatus is the apparatus that realizes chemical vapor deposition on the surface of the substrate. As a typical CVD apparatus, MOCVD (Metalorganic Chemical Vapor Deposition) apparatus is capable of providing the temperature, pressure, chemical gas composition and other conditions required to grow a luminous crystal structure, e.g., GaN (Gallium Nitride), on a surface of a substrate (e.g., a sapphire substrate).

The MOCVD apparatus is provided with a vacuum process chamber, a susceptor is arranged in the process chamber, and a rotating tube is arranged below the susceptor and supports the susceptor. The rotation of the susceptor is achieved by driving the rotating tube to rotate about its central axis (through the friction between the rotating tube and the susceptor). A gap is formed between the outer periphery of the bottom of the susceptor and the inner wall of the rotating tube. By the gap, the fact that the rotating tube is broken by thermal expansion of the rotating tube in high-temperature environments is avoided, and the contact area of the rotating tube and the susceptor is reduced, thereby reducing the heat loss caused by heat transfer between the susceptor and the rotating tube. A heating lamp is located below the susceptor and within an area enclosed by the rotating tube, to provide thermal energy to the susceptor and transfer the thermal energy to the substrate. Process gases are introduced into the process chamber through a gas inlet device (e.g., a shower head) and delivered to surfaces of a plurality of substrates placed on the susceptor for chemical reaction, thereby growing a specific crystal structure such as a GaN structure.

In a CVD process, especially the MOCVD process, in order to prevent quality defects in the thin film grown on the substrate, ensuring the uniformity of substrate surface temperature is an important factor to ensure process effects. When the rotating tube rotates at a high speed, relative movement in the horizontal direction between the susceptor and the rotating tube cannot be avoided due to the above-mentioned gap, causing the rotation of the susceptor and the rotating tube to be non-concentric and asynchronous. Not only is it easy to damage the rotating tube, but it also causes uneven heating of the susceptor, thereby affecting the uniformity of the substrate surface temperature.

### SUMMARY

The present invention aims to provide a substrate supporting device, which realizes synchronous rotation of a rotating tube and a susceptor by limiting relative movement of the two in the horizontal direction during rotation, thereby enabling the susceptor to be uniformly heated, and further ensuring the uniformity of substrate surface temperature.

In order to achieve the above objectives, the present invention provides a substrate supporting device applied to substrate processing apparatus. The substrate processing apparatus includes a process chamber. The substrate supporting device includes:
a susceptor, arranged in the process chamber for supporting a substrate, the bottom surface of the susceptor being provided with a first limiting portion; and
a rotating tube, having a cylindrical structure, arranged below the susceptor and supporting the susceptor, the side wall of the rotating tube being provided with a second limiting portion corresponding to the first limiting portion in position, and relative movement between the rotating tube and the susceptor in the horizontal direction being limited when the two rotate through cooperation of the first limiting portion and the corresponding second limiting portion.

The second limiting portion is arranged outside the side wall of the rotating tube.

A uniform heat conducting portion is arranged in the central area of the bottom surface of the susceptor and is configured to uniformly transfer heat radiated by a heater below the susceptor to the substrate placed on the susceptor; and the upper edge of the rotating tube is arranged around the outer periphery of the uniform heat conducting portion and is located between the first limiting portion and the uniform heat conducting portion.

The uniform heat conducting portion has a disk shape, and the inner diameter of the rotating tube is greater than the outer diameter of the uniform heat conducting portion.

The first limiting portion includes a plurality of bosses arranged on the bottom surface of the susceptor, and the plurality of bosses are distributed along the circumferential direction of the susceptor and respectively correspond to different positions on the outer edge of the susceptor; the second limiting portion includes a plurality of limiting grooves corresponding to the plurality of bosses respectively; and the bosses are respectively embedded in the corresponding limiting grooves.

The second limiting portion includes a plurality of paired limiting blocks arranged on the side wall of the rotating tube, and the limiting grooves are formed between the paired limiting blocks.

The second limiting portion includes a limiting ring arranged around the side wall of the rotating tube, and the plurality of limiting grooves are distributed on the top surface of the limiting ring along the circumferential direction of the limiting ring.

The second limiting portion is arranged at the top of the outer side wall of the rotating tube; the number of the bosses is at least three, and the plurality of bosses are uniformly distributed.

At least one of the boss and the corresponding limiting groove is inclined; the boss gradually shrinks inwards from the top of the inclined boss to the bottom; and the inclined limiting groove has a structure with a wide top and a narrow bottom.

The first limiting portion includes a plurality of limiting grooves, the plurality of limiting grooves are distributed along the circumferential direction of the susceptor and respectively correspond to different positions on the outer edge of the susceptor; the second limiting portion includes a plurality of bosses arranged on the side wall of the rotating tube, and the plurality of bosses are respectively embedded in the plurality of limiting grooves.

The first limiting portion comprises a plurality of paired limiting blocks arranged on the bottom surface of the susceptor, and the limiting grooves are formed between the paired limiting blocks.

The first limiting portion comprises a limiting ring arranged on the bottom surface of the susceptor, and the plurality of limiting grooves are distributed on the bottom surface of the limiting ring along the circumferential direction of the limiting ring.

At least one of the boss and the corresponding limiting groove is inclined; the boss gradually shrinks inwards from the bottom of the inclined boss to the top; and the inclined limiting groove has a structure with a narrow top and a wide bottom.

The second limiting portion is arranged at the top of the outer side wall of the rotating tube; the number of the limiting grooves is at least three, and the plurality of limiting grooves are uniformly distributed.

The boss is in line contact or surface contact with the corresponding limiting groove.

An angle of the inclination is 20° to 70°.

The top surface of the rotating tube is in sealing contact with the bottom surface of the susceptor.

The substrate supporting device further includes a driving device, configured to drive the rotating tube to rotate about its central axis.

The central area of a top surface of the susceptor is provided with a concave portion for accommodating the substrate, the inner wall of the concave portion is provided with a plurality of protrusions extending inwards along the circumferential direction of the concave portion, and the substrate is supported by top surfaces of the protrusions.

The susceptor and the rotating tube are made of any one selected from graphite, quartz, graphite-coated SiC, graphite-coated TaC, graphite-coated WC, graphite-coated NbC, graphite-coated MoC, pure BC, BN, SiC, TaC, AlC, AlN, NbC, NbN and Al2O3.

The present invention also provides substrate processing apparatus. The process chamber of the substrate processing apparatus internally includes:
the substrate supporting device according to the present invention.

Compared with the prior art, the present invention has the following beneficial effects:

1) according to the substrate supporting device of the present invention, during rotation, the relative movement of the rotating tube and the susceptor in the horizontal direction is limited through cooperation of the first limiting portion arranged at the bottom of the susceptor and the second limiting portion arranged on the side wall of the rotating tube; and synchronous rotation of the rotating tube and the susceptor is realized, thereby enabling the susceptor to be uniformly heated, and further ensuring the uniformity of the substrate surface temperature;

2) the second limiting portion is arranged on the side wall of the rotating tube, the structure of the top surface of the rotating tube is not changed, and the first limiting portion also does not interfere with the top surface of the rotating tube, thereby effectively ensuring the sealing contact between the top surface of the rotating tube and the bottom surface of the susceptor, preventing the process gas in the process chamber from entering the rotating tube to corrode the heater in the rotating tube, and meanwhile, preventing stray light from the heater from entering the process chamber through a gap between the top surface of the rotating tube and the bottom surface of the susceptor, so that the temperature in the process chamber is not disturbed by the stray light;

3) the disk-shaped uniform heat conducting portion is arranged in the central area (correspond to the position where the substrate is placed on the susceptor) of the bottom surface of the susceptor, the heat radiated by the heater below the susceptor is firstly absorbed by the uniform heat conducting portion, and as the uniform heat conducting portion has a thickness, the uniform heat conducting portion can uniformly radiate the absorbed heat to the substrate, thereby effectively ensuring the uniformity of the surface temperature of the substrate; and the uniform heat conducting portion is located at the inner side of the rotating tube and can contact the inner side wall of the rotating tube when being subjected to thermal expansion at a certain temperature, thereby having an auxiliary effect on limiting the relative displacement between the rotating tube and the susceptor;

4) the second limiting portion is arranged on the outer wall, which does not interfere with the inner structure of the rotating tube and does not need to reduce the radius of the uniform heat conducting portion, thereby further ensuring the uniformity of the substrate surface temperature; and

5) at least one of the boss and the corresponding limiting groove is inclined, thereby realizing self-centering of the susceptor and the rotating tube; and meanwhile, the boss is in line contact with the limiting groove, thereby reducing the friction between the boss and the limiting groove, and enabling the susceptor to be self-centered with the rotating tube more easily.

### BRIEF DESCRIPTION OF THE DRAWINGS

FIG. 1 is a schematic diagram of substrate processing apparatus;

FIG. 2 is a schematic diagram showing the eccentric rotation of a susceptor and a rotating tube in FIG. 1;

FIG. 3 is an A-A view of FIG. 2;

FIG. 4 is a three-dimensional view of a susceptor and a rotating tube of a substrate supporting device in Embodiment 1 of the present invention;

FIG. 4A is a bottom view of FIG. 4;

FIG. 5 and FIG. 6 are schematic diagrams of different formation modes of a limiting groove in Embodiment 1 of the present invention;

FIG. 6A is a bottom view of FIG. 6;

FIG. 7 is a three-dimensional view of a susceptor and a rotating tube of a substrate supporting device in Embodiment 2 of the present invention;

FIG. 7A is a bottom view of FIG. 7;

FIG. 8 is a schematic diagram of another formation mode of a limiting groove in Embodiment 2 of the present invention;

FIG. 9 is a three-dimensional view of a susceptor and a rotating tube in Embodiment 3 of the present invention;

FIG. 9A is a schematic diagram with both a boss and a limiting groove inclined and with the boss and the limiting groove in face contact in Embodiment 3 of the present invention;

FIG. 9B is a schematic diagram with both the boss and the limiting groove inclined and with the boss and the limiting groove in line contact in Embodiment 3 of the present invention;

FIG. 9C is a schematic diagram with the boss not inclined and the limiting groove inclined in Embodiment 3 of the present invention;

FIG. 9D is a schematic diagram with the boss inclined and the limiting groove not inclined in Embodiment 3 of the present invention;

FIG. 10A is a schematic diagram with both a boss and a limiting groove inclined and with the boss and the limiting groove in face contact in Embodiment 4 of the present invention;

FIG. 10B is a schematic diagram with both the boss and the limiting groove inclined and with the boss and the limiting groove in line contact in Embodiment 4 of the present invention;

FIG. 10C is a schematic diagram with the boss not inclined and the limiting groove inclined in Embodiment 4 of the present invention;

FIG. 10D is a schematic diagram with the boss inclined and the limiting groove not inclined in Embodiment 4 of the present invention;

FIG. 11 is a sectional view of a susceptor and a rotating tube in Embodiment 5 of the present invention; and

FIG. 12 is a schematic diagram of a substrate processing device of the present invention.

### DETAILED DESCRIPTION

The present invention is described in further detail hereinafter in conjunction with the drawings and specific embodiments. Advantages and features of that present invention will become more apparent from the follow description and claims. It is to be noted that the appended drawings are in very simplified forms and use non-precise ratios, merely for convenience and clarity in aid of illustrating the embodiments of the present invention.

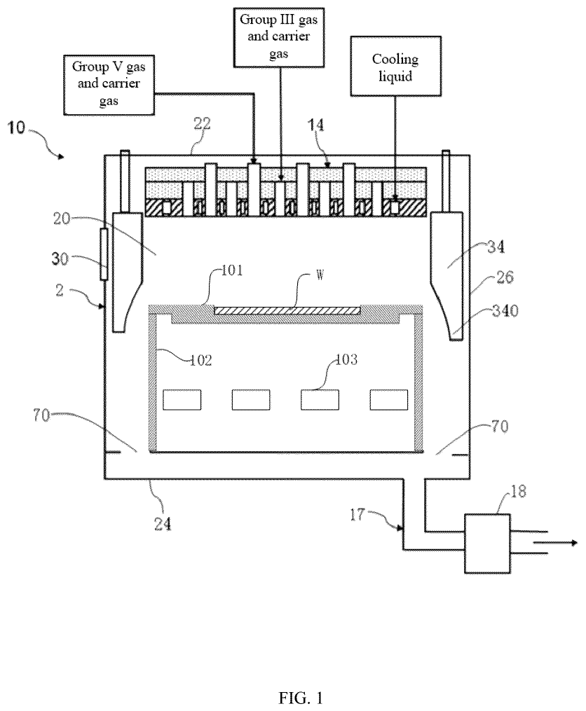

FIG. 1 shows a substrate processing apparatus 10 (which is an MOCVD apparatus). The substrate processing apparatus 10 includes a process chamber 2 having a gas inlet device 14 and a gas exhaust device 17. The gas inlet device 14 may be arranged at the top of the process chamber 2, and the gas exhaust device 17 may be arranged at the bottom of the process chamber 2, or the gas inlet device 14 and the gas exhaust device 17 may be arranged at opposite ends of the side walls of the process chamber.

The process chamber 2 has a top wall 22 at the top, a bottom wall 24 at the bottom, and a cylindrical side wall 26 extending between the top wall 22 and the bottom wall 24. The top wall 22, the bottom wall 24, and the side wall 26 together form an airtight inner processing space 20 for accommodating gas emitted from the gas inlet device 14. Although the process chamber 2 shown in FIG. 1 is cylindrical, other substrate processing apparatus 10 may include process chambers 2 of other shapes, such as conical, square, hexagonal, octagonal, or any other suitable shape.

A temperature measuring probe (not shown in the figure) connected to an outer temperature monitoring device is also arranged in the inner processing space 20 to monitor temperature in the process chamber 2 during the process.

The gas inlet device 14 is connected to a gas source for supplying a process gas. The process gas may include carrier gas and process gas. The process gas may include group III gases and group V gases. In a typical metalorganic chemical vapor deposition process, the carrier gas may be nitrogen, hydrogen, or a mixture of nitrogen and hydrogen. The gas inlet device 14 is configured to receive various gases and guide the process gases to flow generally in a downward direction.

The inside of the gas inlet device 14 is also provided with a fluid channel communicated with an outer cooling system. Though cooling liquid in the fluid channel, the temperature of the gas inlet device 14 is maintained at a desired temperature during the process. The top wall 22, the bottom wall 24, and the side wall 26 of the process chamber 2 may all be provided with similar fluid channels (not shown).

The gas exhaust device 17 is configured to exhaust gases from the inner processing space 20 of the process chamber 2 (including both waste gas generated by the reaction and part of the gas that did not participate in the reaction in time). The gas exhaust device 17 includes a gas outlet 70 disposed at or adjacent the bottom of the process chamber 2, and a pump 18 disposed outside the process chamber 2 and communicated with the gas outlet 70, and gas flow power is provided by the pump 18.

The process chamber 2 is also provided with a substrate access port 30 for moving the substrate W in and out, and an annular process chamber liner 34 arranged adjacent to the side wall 26 and capable of moving up and down. The process chamber liner 34 has an upper closed position and a lower open position. After the substrate W treatment is completed, the process chamber liner 34 can be moved downward (to the open position) to expose the substrate access port 30, and the substrate W can be moved out from the substrate access port 30. The next batch of substrates W to be processed can also be moved in from the substrate access port 30. After the substrate W is moved in, the process chamber liner 34 can be moved upward (to the closed position) to cover the substrate access port 30, thereby separating the inner processing space 20 from the substrate access port 30. When in the closed position, the area defined by the process chamber liner 34 is symmetrical and circular, and the substrate access port 30 is “hidden” behind the process chamber liner 34 so as not to come into contact with the process gas. The area to which the process gas is exposed is a circumferential boundary defined by the process chamber liner 34, which ensures the uniformity of the entire process environment. A driving mechanism (not shown) for controlling and driving up and down movement of the process chamber liner 34 may be any type of drive, e.g., mechanical, electromechanical, hydraulic, or pneumatic drive.

Although the shown process chamber liner 34 is cylindrical, it may be of other shapes, e.g., square, hexagonal, octagonal, or any other suitable shape.

The process chamber 2 is also provided with a susceptor 101, a rotating tube 102, and a plurality of heaters 103. The susceptor 101 is generally disk-shaped, and the rotating tube 102 is arranged below the susceptor and supports the susceptor 101. The heater 103 is arranged below the susceptor and in an area enclosed by the rotating tube 102 for radiating thermal energy to the susceptor 101, and the susceptor 101 then transfers the thermal energy provided by the heater 103 to the substrate W. The external controller will adjust heating power of the heater 103 according to a temperature value fed back by the temperature measuring probe. Ideally, the susceptor 101 is in sealing contact with the rotating tube 102, and the rotating tube 102 prevents the process gas from penetrating into the rotating tube interior and corroding components within the rotating tube. Meanwhile, the rotating tube 102 prevents the stray light of the heater 103 from entering the inner processing space 20 and interfering with the temperature value obtained by the temperature measuring probe. A thermal protection shield (not shown in the figure) may also be arranged below the heater. For example, the thermal protection shield is arranged to be parallel to the susceptor 101, so as to help guide heat transfer from the heater 103 upward toward the susceptor 101 rather than downward toward the bottom wall 24 at the bottom of the process chamber 2.

During the process, multiple process gases from the gas inlet device 14 are partially mixed during downward diffusion, but sufficient mixing when reaching the upper surface of the susceptor cannot be guaranteed. Therefore, it is necessary to drive the rotating tube 102 maintain high speed rotation (600-1200 r/min), and the susceptor 101 is driven to rotate at a high speed under the friction between the rotating tube 102 and the susceptor 101. In this way, the different kinds of process gases reaching the upper surface of the susceptor are sufficiently mixed under the drive of the high-speed rotating susceptor 101.

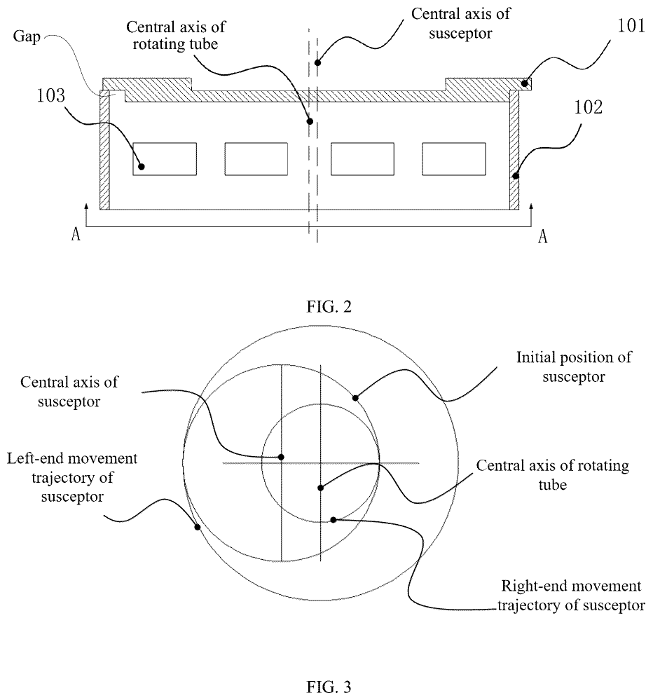

As shown in FIG. 1 and FIG. 2, there is a gap between the outer periphery of the bottom of the susceptor and the inner wall of the rotating tube. By the gap, the fact that the rotating tube 102 is broken by thermal expansion of the rotating tube 102 in high-temperature environments is avoided. Meanwhile, the contact area between the rotating tube 102 and the susceptor 101 can be reduced, thereby reducing heat loss caused by heat transfer between the susceptor 101 and the rotating tube 102.

FIG. 3 is an A-A view of FIG. 2. FIG. 3 shows the trajectory of the rotating tube 102 rotating at a high speed. Relative movement in the horizontal direction between the susceptor 101 and the rotating tube 102 cannot be avoided due to the above-mentioned gap, causing the rotation of the susceptor 101 and the rotating tube 102 to be non-concentric and asynchronous. Not only is the rotating tube 102 easily damaged, but the susceptor 101 is also heated unevenly, thus affecting the uniformity of the substrate surface temperature. How to maintain the uniformity of the substrate surface temperature and prevent quality defects in the thin film on the substrate W during the CVD process is a concern in the industry.

### Embodiment 1

The present invention provides a substrate supporting device applied to substrate processing apparatus. The substrate processing apparatus includes a process chamber. The substrate supporting device includes a susceptor 201, a rotating tube 202, a first limiting portion, a second limiting portion, and a rotation driving device (not shown in the figure).

The susceptor 201 has a disk-shaped structure and is arranged in the process chamber for carrying a substrate. The bottom surface of the susceptor is provided with a first limiting portion. The rotating tube 202 has a cylindrical structure, which is arranged below the susceptor and supports the susceptor 201. The bottom of the rotating tube is connected to the driving rotation device by a flange, and the rotation driving device drives the rotating tube 202 and the susceptor 201 to rotate about the central axis of the rotating tube. The rotation driving device in this embodiment is a permanent magnet motor. The side wall of the rotating tube is provided with a second limiting portion corresponding to the first limiting portion in position. Relative movement of the rotating tube 202 and the susceptor 201 in the horizontal direction is limited when the two rotate through cooperation between the first limiting portion and the second limiting portion.

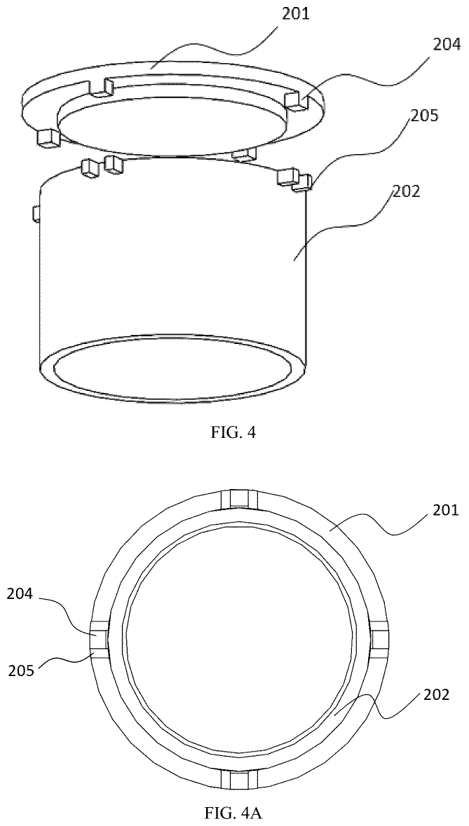

As shown in FIG. 4 and FIG. 4A, the first limiting portion includes a plurality of bosses 204 arranged on the bottom surface of the susceptor. The plurality of bosses 204 are distributed along the circumferential direction of the susceptor 201 and respectively correspond to different positions on the outer edge of the susceptor. In a preferred embodiment, the number of the bosses 204 is at least three, optionally, four as shown in FIG. 4, and the plurality of bosses 204 are uniformly distributed on the bottom surface of the susceptor along the circumferential direction of the susceptor 201.

In this embodiment, the boss 204 is integrally fabricated with the susceptor 201. In other embodiments, the boss 204 and the susceptor 201 may also be fixedly connected by means of a connecting member (such as a bolt).

The second limiting portion includes a plurality of limiting grooves respectively corresponding to the plurality of bosses 204, and one boss 204 corresponds to one limiting groove. By embedding the boss 204 in the corresponding limiting groove, the susceptor 201 and the rotating tube 202 are detachably connected, and the relative movement of the rotating tube 202 and the susceptor 201 in the horizontal direction is limited when the two rotate. The second limiting portion may be arranged outside or inside the side wall of the rotating tube. In a preferred embodiment, the second limiting portion is generally arranged outside the side wall of the rotating tube to facilitate observation of the centering of the boss 204 and the limiting groove. And as the second limiting portion is arranged on the outer side wall of the rotating tube, arrangement of components in the rotating tube 202 does not need to be changed, and heating uniformity of the susceptor 201 by the heater is not affected.

The limiting groove has a variety of formation modes.

1) In this embodiment, as shown in FIG. 4 and FIG. 4A, the second limiting portion includes a plurality of paired limiting blocks 205 arranged around the side wall of the rotating tube. The plurality of paired limiting blocks 205 are distributed along the circumferential direction of the rotating tube 202 and respectively correspond to different bosses 204. Two paired limiting blocks 205 are arranged along the circumferential direction of the rotating tube 202 instead of being arranged vertically, and a gap is formed between the two limiting blocks 205, which forms the limiting groove. In order to facilitate the centering of the boss 204 and the limiting groove, in this embodiment, the plurality of paired limiting blocks 205 are all arranged at the top of the side wall of the rotating tube and at approximately the same height.

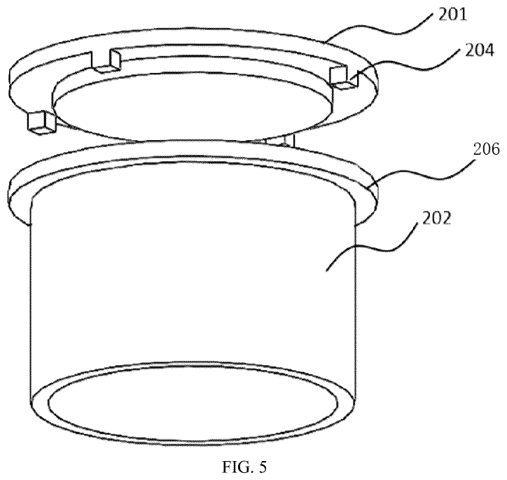

2) In another embodiment, as shown in FIG. 5, the second limiting portion includes a limiting ring 206 arranged around the side wall of the rotating tube. A plurality of limiting grooves are distributed on the top face of the limiting ring along the circumferential direction of the limiting ring 206 (fitting the bottom surface of the susceptor to the top surface of the rotating tube is realized by controlling one or more of the arrangement height of the limiting ring 206 on the side wall of the rotating tube and the depth of the limiting groove). In a preferred embodiment, the limiting ring 206 is coaxial with the rotating tube 202. The limiting groove may also be a through groove penetrating through the top and bottom surfaces of the limiting ring.

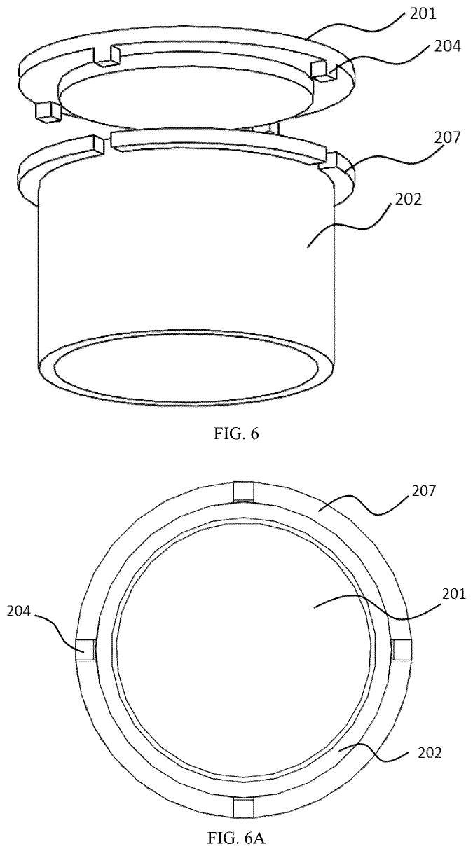

3) as shown in FIG. 6 and FIG. 6A, the second limiting portion includes a plurality of limiting arcs 207 arranged on the side wall of the rotating tube along the circumferential direction of the rotating tube 202. The plurality of limiting arcs 207 have approximately the same height and are concentric with the rotating tube 202. A gap is formed between two adjacent limiting arcs 207, which forms the limiting groove.

In this embodiment, The side wall of the boss 204 is perpendicular to a horizontal plane (the boss 204 is not inclined). The boss 204 may be any one of a cylindrical shape and a polygonal cylindrical shape (e.g., the rectangular parallelepiped shape shown in FIGS. 4 to 6). The limiting groove has a shape matching with the boss 204, and the boss 204 is in face contact with the limiting groove.

In this embodiment, the susceptor 201, the boss 204, the rotating tube 202, the limiting block 205, the limiting ring and the limiting arc 207 are made of any one selected from graphite, quartz, graphite-coated SiC, graphite-coated TaC, graphite-coated WC, graphite-coated NbC, graphite-coated MoC, pure BC, BN, SiC, TaC, AlC, AlN, NbC, NbN and Al₂O₃.

According to the substrate supporting device of the present invention, the relative movement of the rotating tube 202 and the susceptor 201 in the horizontal direction is limited when the two rotate through cooperation of the first limiting portion arranged at the bottom of the susceptor and the second limiting portion arranged on the side wall of the rotating tube. Synchronous and concentric rotation of the rotating tube 202 and the susceptor 201 is realized, thereby enabling the susceptor 201 to be uniformly heated, and further ensuring the uniformity of the substrate surface temperature.

A limiting groove is not directly formed on the top face of the rotating tube, and the boss 204 is also kept away from the top surface of the rotating tube. Therefore, sealing contact between the top face of the rotating tube and the bottom surface of the susceptor is not damaged in the present invention. The substrate supporting device of the present invention can prevent the process gas in the process chamber from entering the rotating tube to corrode the heater 203 inside the rotating tube, and can also prevent the stray light from the heater 203 from entering the process chamber to interfere with the temperature measurement probe detecting the temperature inside the process chamber.

### Embodiment 2

In this embodiment. In this embodiment, the bottom surface of the susceptor is provided with a first limiting portion. The side wall (preferably the outer side wall) of the rotating tube is provided with a second limiting portion corresponding to the first limiting portion. The first limiting portion includes a plurality of limiting grooves distributed along the circumferential direction of the susceptor 301 and respectively corresponding to different positions of the outer edge of the susceptor. The second limiting portion includes a plurality of bosses 304 arranged on the outer side wall of the rotating tube along a circumferential direction of the rotating tube 302. By embedding the plurality of bosses 304 in the plurality of limiting grooves respectively, detachable connection between the rotating tube 302 and the susceptor 301 is realized, and relative movement of the rotating tube 302 and the susceptor in a horizontal direction is limited when rotating.

In this embodiment, the plurality of bosses 304 are uniformly distributed, and the second limiting portion includes at least three bosses 304. In order to facilitate the centering of the boss 304 and the limiting groove, in a preferred embodiment, the plurality of bosses 304 are arranged at the top of the outer side wall of the rotating tube and have approximately the same height.

The limiting groove in this embodiment has a variety of formation modes.

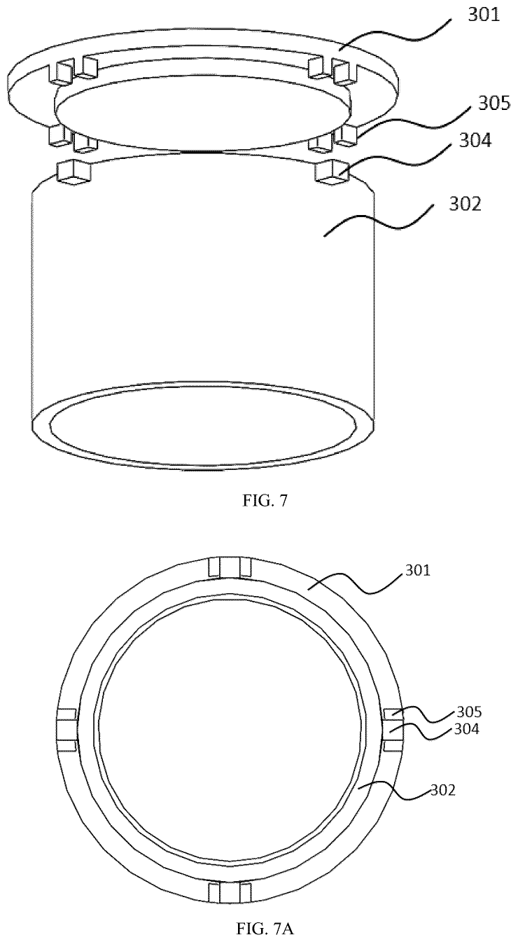

As shown in FIG. 7 and FIG. 7A, the first limiting portion includes a plurality of paired limiting blocks 305 arranged on the bottom surface of the susceptor along the circumferential direction of the susceptor 301, and each limiting blocks 305 corresponds to one boss 304. Two paired limiting blocks 305 are arranged along the circumferential direction of the susceptor 301, a gap is formed between the two limiting blocks 305, and the gap forms the limiting groove.

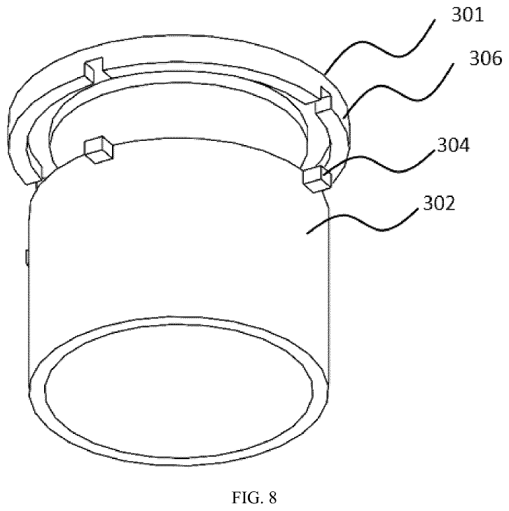

In another embodiment, as shown in FIG. 8, the first limiting portion includes a limiting ring 306 (concentric with the susceptor 301) arranged on the bottom surface of the susceptor, and a plurality of limiting grooves are distributed on the bottom surface of the limiting ring along the circumferential direction of the limiting ring 306. The inner diameter of the limiting ring is not less than an outer diameter of the rotating tube 302, and the outer diameter of the limiting ring is not greater than a diameter of the susceptor. In FIG. 8, the inner diameter of the limiting ring is equal to the outer diameter of the rotating tube, and the outer diameter of the limiting ring is equal to the diameter of the susceptor. Fitting the bottom surface of the susceptor to the top surface of the rotating tube (the susceptor 301 is in sealing contact with the rotating tube 302) is realized by controlling one or more of the arrangement height of the boss 304 on the side wall of the rotating tube and the depth of the limiting groove.

The side wall of the boss 304 in this embodiment is perpendicular to a horizontal plane (the boss 304 is not inclined), and the limiting groove has a shape matching with the boss 304. The boss 304 is in face contact with the limiting groove.

### Embodiment 3

In this embodiment, at least one of the boss 404 and the corresponding limiting groove is inclined to facilitate self-centering between the susceptor 401 and the rotating tube 402. The boss 404 may be in face contact or line contact with the limiting groove 4051. When the boss 404 is in line contact with the limiting groove, as the friction between the boss 404 and the limiting groove is reduced, under the action of the gravity of the susceptor 401, the susceptor 401 is not only easily self-centered with the rotating tube 402, but also can effectively ensure that the bottom surface of the susceptor is fitted to the top surface of the rotating tube. In this embodiment, an angle of the inclination is 20° to 70°.

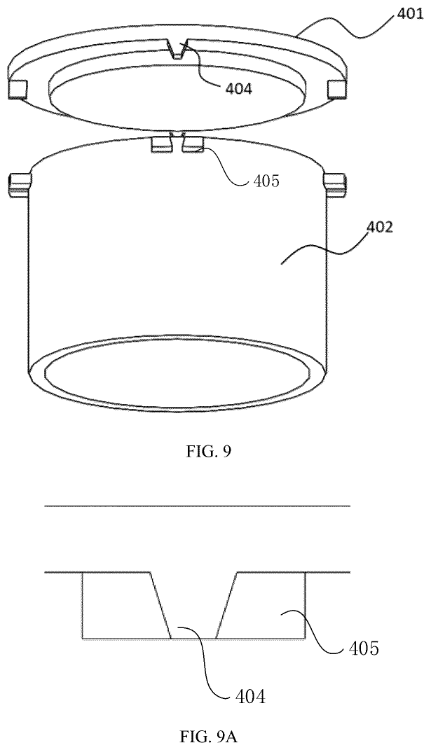

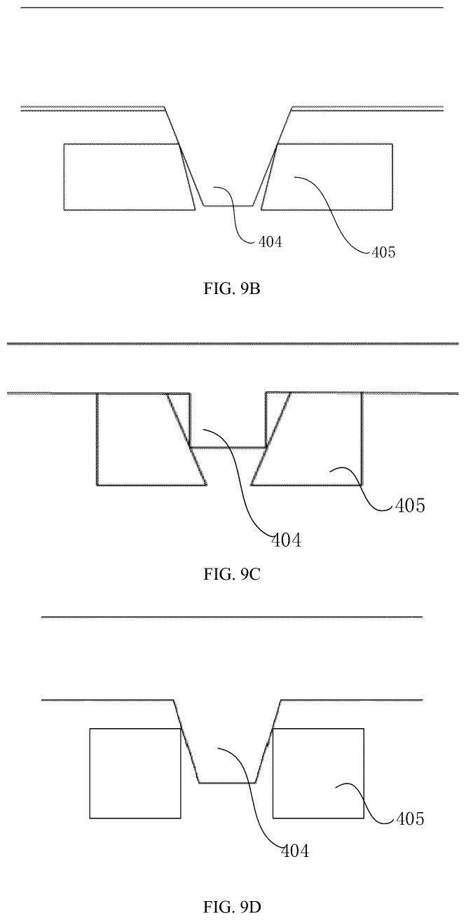

In this embodiment, as shown in FIG. 9, the first limiting portion includes a plurality of bosses 404 arranged on the bottom surface of the substrate carrier, and the limiting grooves are formed by means of the paired limiting blocks 405 arranged on the side wall of the rotating tube. The boss 404 and the corresponding limiting groove include following several situations.

1) As shown in FIG. 9, both the boss 404 and the corresponding limiting groove are inclined. The boss 404 gradually shrinks inwards from the top of the inclined boss 404 to the bottom. The inclined limiting groove has a structure with a wide top and a narrow bottom. As shown in FIG. 9A, the boss 404 and the corresponding limiting groove have the same inclination angle, and the boss 404 is in face contact with the limiting groove. Or, as shown in FIG. 9B, the inclination angle of the limiting groove is less than that of the boss 404, and the boss 404 is in line contact with the limiting groove. In the present invention, the inclination angle of the limiting groove refers to an included angle (acute angle) between the side wall of the limiting groove and a horizontal plane, and the inclination angle of the boss 404 refers to an included angle (acute angle) between the side wall of the boss and the horizontal plane.

2) As shown in FIG. 9C, the boss 404 is not inclined, and the corresponding limiting groove is inclined. The limiting groove has a structure with a wide top and a narrow bottom, and the width of the top of the limiting groove is greater than that of the boss 404, and a width of the bottom of the limiting groove is less than that of the boss 404. The boss 404 is in line contact with the limiting groove.

3) As shown in FIG. 9D, the boss 404 is inclined, and the corresponding limiting groove is not inclined. The boss 404 gradually shrinks inwards from the top of the inclined boss 404 to the bottom. A width of the limiting groove is greater than that of the bottom of the boss 404 and is not greater than that of the top of the boss 404. The limiting groove is in line contact with the boss 404.

In this embodiment, fitting the bottom surface of the susceptor to the top surface of the rotating tube is realized by controlling one or more of the arrangement height of the limiting groove on the side wall of the rotating tube, the depth of the limiting groove, the inclination angle of the limiting groove, the width of the limiting groove, the inclination angle of the boss 404 and the width of the boss 404.

### Embodiment 4

In this embodiment, a second limiting portion includes a plurality of bosses 504 arranged on a side wall of the rotating tube. At least one of the boss 504 and the corresponding limiting groove is inclined. The boss 504 and the corresponding limiting groove include following several situations.

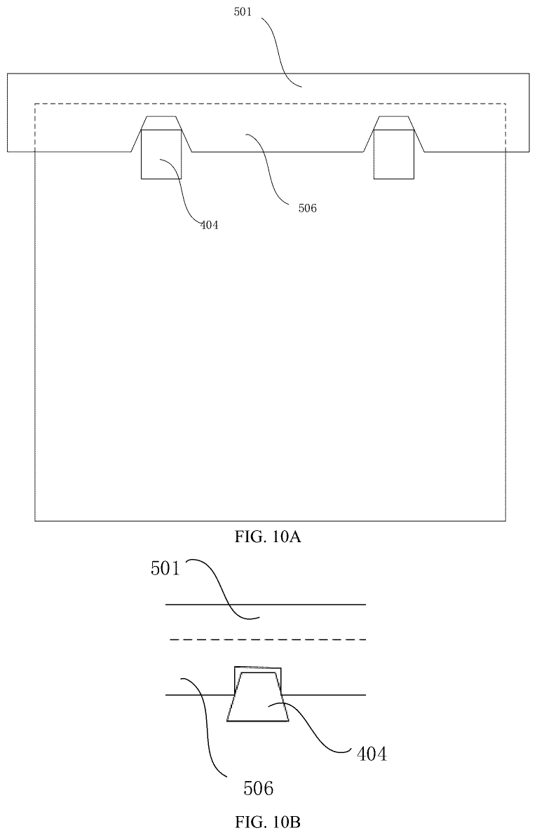

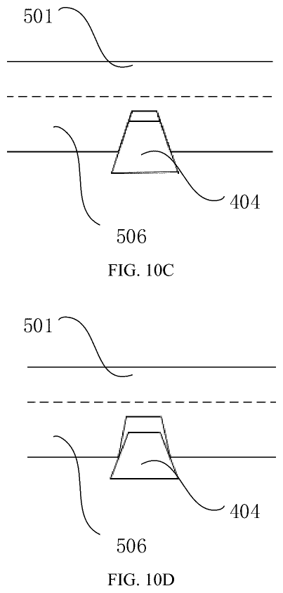

1) As shown in FIG. 10A, in this embodiment, the first limiting portion includes a limiting ring 506 arranged at the bottom of a susceptor 501, and a plurality of limiting grooves are formed on the bottom surface of the limiting ring 506. In FIG. 10A, the boss 504 is not inclined, and the corresponding limiting groove is inclined. The limiting groove has a structure with a narrow top and a wide bottom, the width of the bottom of the limiting groove is greater than that of the boss 504, and the width of the top of the limiting groove is less than that of the boss 504. The boss 504 is in line contact with the limiting groove.

2) As shown in FIG. 10B, the boss 504 is inclined, and the corresponding limiting groove is not inclined. The boss 504 gradually shrinks inwards from the bottom of the inclined boss 504 to the top. The width of the limiting groove is greater than that of the top of the boss 504 and is not greater than that of the bottom of the boss 504. The limiting groove is in line contact with the boss 504.

3) As shown in FIG. 10C, both the boss 504 and the limiting groove are inclined. The boss 504 gradually shrinks inwards from the bottom of the inclined boss 504 to the top. The inclined limiting groove has a structure with a narrow top and a wide bottom. As shown in FIG. 10C, the boss 504 and the corresponding limiting groove have the same inclination angle, and the boss 504 is in face contact with the limiting groove. Or, as shown in FIG. 10D, the inclination angle of the limiting groove is less than that of the boss 504, and the boss 504 is in line contact with the limiting groove.

### Embodiment 5

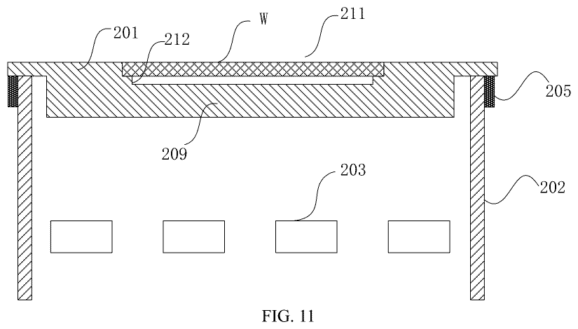

FIG. 11 shows a substrate supporting device of the present invention. As shown in FIG. 11, the top surface of a susceptor 201 is provided with a circular concave portion 211 (concentric with the susceptor 201) for accommodating a substrate W. The inner wall of the concave portion 211 is provided with a plurality of protrusions 212 extending inwards along the circumferential direction of the concave portion 211. The substrate W is supported by the top surfaces of the protrusions 212, and the friction between the susceptor 201 and the substrate W is reduced.

A uniform heat conducting portion 209 is arranged on the bottom surface of the susceptor. In this embodiment, the uniform heat conducting portion 209 is disk-shaped, and the diameter of the uniform heat conducting portion 209 is greater than that of the concave portion 211. Due to the concave portion 211, the central area of the susceptor 201 becomes thinner, and the distance between the substrate W and a heater 203 is relatively short, which is likely to cause uneven heating of the substrate W. By means of the heat conducting portion 209, the thickness loss of the central area of the susceptor 201 is compensated, thereby enabling heat radiated by the heater to be uniformly transferred to the substrate W placed on the susceptor 201.

As shown in FIG. 11, a plurality of paired limiting blocks 205 are arranged on the outer wall of the rotating tube. The inner diameter of the rotating tube 202 is greater than the outer diameter of the uniform heat conducting portion 209. At certain temperature, thermal expansion will make contact between the uniform heat conducting portion 209 and the inner side wall of the rotating tube (but the force is small and will not damage the rotating tube), which assists in limiting relative displacement between the rotating tube 202 and the susceptor 201.

The second limiting portion is arranged on the outer wall of the rotating tube rather than between the inner side wall of the rotating tube and the outer side wall of the uniform heat conducting portion, and thus there is no need to reduce the radius of the uniform heat conducting portion 209, and further ensuring uniformity of substrate surface temperature.

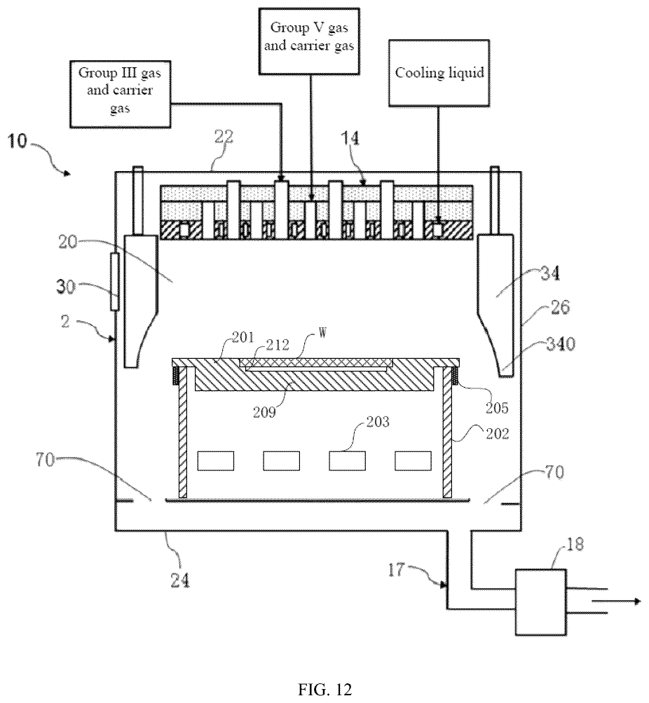

The present invention also provides substrate processing apparatus. As shown in FIG. 12, the process chamber of the substrate processing apparatus internally includes:
the substrate supporting device according to the present invention.

While the present invention has been described in detail with reference to the preferred embodiments, it should be understood that the above description should not be taken as limiting the invention. Various modifications and alternatives to the present invention will become apparent to those skilled in the art upon reading the foregoing disclosure. Accordingly, the protection scope of the present invention shall be limited by the appended claims.

1. A substrate supporting device, applied to substrate processing apparatus, the substrate processing apparatus comprising a process chamber, wherein the substrate supporting device comprises:
a susceptor, arranged in the process chamber for supporting a substrate, the bottom surface of the susceptor being provided with a first limiting portion; and
a rotating tube, having a cylindrical structure, arranged below the susceptor and supporting the susceptor, the side wall of the rotating tube being provided with a second limiting portion corresponding to the first limiting portion in position, and relative movement between the rotating tube and the susceptor in the horizontal direction being limited when the two rotate through cooperation of the first limiting portion and the corresponding second limiting portion.

2. The substrate supporting device of claim 1, wherein the second limiting portion is arranged outside the side wall of the rotating tube.

3. The substrate supporting device of claim 1, wherein a uniform heat conducting portion is arranged in the central area of the bottom surface of the susceptor and is configured to uniformly transfer heat radiated by a heater below the susceptor to the substrate placed on the susceptor; and the upper edge of the rotating tube is arranged around the outer periphery of the uniform heat conducting portion and is located between the first limiting portion and the uniform heat conducting portion.

4. The substrate supporting device of claim 3, wherein the uniform heat conducting portion has a disk shape, and the inner diameter of the rotating tube is larger than the outer diameter of the uniform heat conducting portion.

5. The substrate supporting device of claim 1, wherein the first limiting portion comprises a plurality of bosses arranged on the bottom surface of the susceptor, and the plurality of bosses are distributed along the circumferential direction of the susceptor and respectively correspond to different positions on the outer edge of the susceptor; the second limiting portion comprises a plurality of limiting grooves corresponding to the plurality of bosses respectively; and the bosses are respectively embedded in the corresponding limiting grooves.

6. The substrate supporting device of claim 5, wherein the second limiting portion comprises a plurality of paired limiting blocks arranged on the side wall of the rotating tube, and the limiting grooves are formed between the paired limiting blocks.

7. The substrate supporting device of claim 5, wherein the second limiting portion comprises a limiting ring arranged around the side wall of the rotating tube, and the plurality of limiting grooves are distributed on the top surface of the limiting ring along the circumferential direction of the limiting ring.

8. The substrate supporting device of claim 5, wherein at least one of the boss and the corresponding limiting groove is inclined; the boss gradually shrinks inwards from the top of the inclined boss to the bottom; and the inclined limiting groove has a structure with a wide top and a narrow bottom.

9. The substrate supporting device of claim 1, wherein the first limiting portion comprises a plurality of limiting grooves, the plurality of limiting grooves are distributed along the circumferential direction of the susceptor and respectively correspond to different positions on the outer edge of the susceptor; the second limiting portion comprises a plurality of bosses arranged on the side wall of the rotating tube, and the plurality of bosses are respectively embedded in the plurality of limiting grooves.

10. The substrate supporting device of claim 9, wherein the first limiting portion comprises a plurality of paired limiting blocks arranged on the bottom surface of the susceptor, and the limiting grooves are formed between the paired limiting blocks.

11. The substrate supporting device of claim 9, wherein the first limiting portion comprises a limiting ring arranged on the bottom surface of the susceptor, and the plurality of limiting grooves are distributed on the bottom surface of the limiting ring along the circumferential direction of the limiting ring.

12. The substrate supporting device of claim 9, wherein at least one of the boss and the corresponding limiting groove is inclined; the boss gradually shrinks inwards from the bottom of the inclined boss to the top; and the inclined limiting groove has a structure with a narrow top and a wide bottom.

13. The substrate supporting device of claim 5,
wherein the boss is in line contact or surface contact with the corresponding limiting groove.

14. The substrate supporting device of claim 8, wherein the angle of the inclination is 20° to 70°.

15. The substrate supporting device of claim 5, wherein the second limiting portion is arranged at the top of the outer side wall of the rotating tube; the number of the bosses is at least three, and the plurality of bosses are uniformly distributed.

16. The substrate supporting device of claim 9, wherein the second limiting portion is arranged at the top of the outer side wall of the rotating tube; the number of the limiting grooves is at least three, and the plurality of limiting grooves are uniformly distributed.

17. The substrate supporting device of claim 1, wherein the top face of the rotating tube is in sealing contact with the bottom surface of the susceptor.

18. The substrate supporting device of claim 1, further comprising a driving device configured to drive the rotating tube to rotate about its central axis.

19. The substrate supporting device of claim 1, wherein the central area of the top surface of the susceptor is provided with a concave portion for accommodating the substrate, the inner wall of the concave portion is provided with a plurality of protrusions extending inwards along the circumferential direction of the concave portion, and the substrate is supported by top surfaces of the protrusions.

20. The substrate supporting device of claim 1, wherein the susceptor and the rotating tube are made of any one selected from graphite, quartz, graphite-coated SiC, graphite-coated TaC, graphite-coated WC, graphite-coated NbC, graphite-coated MoC, pure BC, BN, SiC, TaC, AlC, AlN, NbC, NbN and Al₂O₃.

21. Substrate processing apparatus, wherein the process chamber of the substrate processing apparatus internally comprises:
the substrate supporting device as set forth in claim 1.

22. The substrate supporting device of claim 9, wherein the boss is in line contact or surface contact with the corresponding limiting groove.

23. The substrate supporting device of claim 12, wherein the angle of the inclination is 20° to 70°.
